(19) United States
(12) Patent Application Publication
(10) Pub. No.: US 2007/0065576 A1
(43) Pub. Date: Mar. 22, 2007

(54) Technique for atomic layer deposition

(76) Inventors: Vikram Singh, North Andover, MA (US); Harold M. Persing, Rockport, MA (US); Edmund J. Winder, Waltham, MA (US); Jeffrey A. Hopwood, Needham, MA (US); Anthony Renau, West Newbury, MA (US)

Correspondence Address: HUNTON & WILLIAMS LLP;INTELLECTUAL PROPERTY DEPARTMENT, 1900 K STREET, N.W., SUITE 1200, WASHINGTON, DC, 20006-1109, US

(21) Appl. No.: 11/221,710

(22) Filed: Sep. 9, 2005

(51) Int. Cl. C23C 16/00

(52) U.S. Cl. 427/248.1; 118/715; 118/723 R

(57) ABSTRACT

A technique for atomic layer deposition is disclosed. In one particular exemplary embodiment, the technique may be realized by an apparatus for atomic layer deposition. The apparatus may comprise a process chamber having a substrate platform to hold at least one substrate. The apparatus may also comprise a supply of a precursor substance, wherein the precursor substance comprises atoms of at least one first species and atoms of at least one second species, and wherein the supply provides the precursor substance to saturate a surface of the at least one substrate. The apparatus may further comprise a plasma source of metastable atoms of at least one third species, wherein the metabstable atoms are capable of desorbing the atoms of the at least one second species from the saturated surface of the at least one substrate to form one or more atomic layers of the at least one first species.

### FIELD OF THE DISCLOSURE

The present disclosure relates generally to semiconductor manufacturing and, more particularly, to a technique for atomic layer deposition.

### BACKGROUND OF THE DISCLOSURE

Modern semiconductor manufacturing has created a need for precision, atomic-level deposition of high quality thin film structures. Responsive to this need, a number of film growth techniques collectively known as “atomic layer deposition” (ALD) or “atomic layer epitaxy” (ALE) have been developed in recent years. ALD technology is capable of depositing uniform and conformal films with atomic layer accuracy. A typical ALD process uses sequential self-limiting surface reactions to achieve control of film growth in the monolayer thickness regime. Due to its excellent potential for film conformity and uniformity, ALD has become the technology of choice for advanced applications such as high dielectric constant (high-k) gate oxide, storage capacitor dielectrics, and copper diffusion barriers in microelectronic devices. In fact, ALD technology may be useful for any advanced application that benefits from precise control of thin film structure on the nanometer (nm) or sub-nanometer scale.

To date, however, most existing deposition techniques suffer from inherent deficiencies and have not been reliably applied to mass production in the semiconductor industry. For example, a deposition technique known as “molecular beam epitaxy” (MBE) uses shutter-controlled individual effusion cells to direct atoms of different species towards a substrate surface, on which these atoms react with each other to form a desired monolayer. In a solid-source MBE process, the effusion cells have to be heated to considerably high temperatures for thermionic emission of the ingredient atoms. In addition, extremely high vacuum has to be maintained to ensure no collision among the ingredient atoms before they reach the substrate surface. Despite the high temperature and high vacuum requirement, MBE film growth rates are quite low for mass production purposes.

Another ALD technique is known as temperature-modulated atomic layer epitaxy (ALE). To grow a silicon film according to this technique, the following steps are repeated. First, a monolayer of silane (SiH₄) is deposited on a substrate surface at a relatively low temperature between 180° C. and 400° C. Then, the substrate temperature is ramped to approximately 550° C. to desorb the hydrogen atoms, leaving behind a monolayer of silicon. Although this technique does achieve a controlled layer-by-layer film growth, the requirement for repeated temperature spikes makes it difficult to maintain uniformity across large wafers and repeatability from layer to layer. Additionally, heating the substrate to high temperatures can damage or destroy delicate structures formed on the substrate in previous processing steps.

One existing ALD technique employs ion bombardment to desorb excess hydrogen atoms. According to this technique, a disilane (Si₂H₆) gas may be used to form a disilane monolayer on a substrate surface. The substrate surface is then bombarded with helium or argon ions to desorb excess hydrogen atoms from the disilane monolayer to form a silicon monolayer. Perhaps due to overly energetic ion bombardments (˜50 eV ion energy), the film growth rate is fairly low (less than 0.15 monolayer per cycle), and energetic ion fluxes are essentially line-of-sight processes which therefore can compromise atomic layer deposition's potential for a highly conformal deposition. Further, the energetic ion can also cause crystalline defects which may necessitate post-deposition annealing.

Further, conformal doping for ALD-deposited thin films, especially in 3-D structures (e.g., FinFETs), remains a challenge to process engineers. Existing ion implantation techniques are undesirable for introducing dopants into a 3-D conformally covered structure, not only because it is hard to achieve uniformity of dopant distribution, but also due to the potential damages that may result from a post-implant anneal.

In view of the foregoing, it would be desirable to provide an atomic layer deposition solution which overcomes the above-described inadequacies and shortcomings.

### SUMMARY OF THE DISCLOSURE

A technique for atomic layer deposition is disclosed. In one particular exemplary embodiment, the technique may be realized by an apparatus for atomic layer deposition. The apparatus may comprise a process chamber having a substrate platform to hold at least one substrate. The apparatus may also comprise a supply of a precursor substance, wherein the precursor substance comprises atoms of at least one first species and atoms of at least one second species, and wherein the supply provides the precursor substance to saturate a surface of the at least one substrate. The apparatus may further comprise a plasma source of metastable atoms of at least one third species, wherein the metabstable atoms are capable of desorbing the atoms of the at least one second species from the saturated surface of the at least one substrate to form one or more atomic layers of the at least one first species.

In another particular exemplary embodiment, the technique may be realized as a method for atomic layer deposition. The method may comprise saturating a substrate surface with a precursor substance having atoms of at least one first species and atoms of at least one second species, thereby forming a monolayer of the precursor substance on the substrate surface. The method may also comprise exposing the substrate surface to plasma-generated metastable atoms of a third species, wherein the metastable atoms desorb the atoms of the at least one second species from the substrate surface to form an atomic layer of the at least one first species. An atomic layer deposition method may comprise multiple deposition cycles to form a plurality of atomic layers of the first species, wherein each deposition cycle repeats the steps as recited above to form one atomic layer of the first species.

In yet another particular exemplary embodiment, the technique may be realized by an apparatus for atomic layer deposition. The apparatus may comprise a process chamber having a substrate platform to hold at least one substrate. The apparatus may also comprise a supply of disilane (Si₂H₆), wherein the supply is adapted to supply a sufficient amount of disilane to saturate a surface of the at least one substrate, a supply of helium. The apparatus may further comprise a plasma chamber coupled to the process chamber, the plasma chamber being adapted to generate helium metastable atoms from helium supplied by the supply of helium. The metabstable atoms may be capable of desorbing hydrogen atoms from the saturated surface of the at least one substrate, thereby forming one or more atomic layers of silicon.

In still another particular exemplary embodiment, the technique may be realized as a method of conformal doping. The method may comprise forming a thin film on a substrate surface in one or more deposition cycles, wherein, in each of the one or more deposition cycles, a precursor substance having atoms of at least one first species and atoms of at least one second species is supplied to saturate the substrate surface, and then the atoms of the at least one second species are desorbed from the saturated substrate surface to form one or more atomic layers of the at least one first species. The method may also comprise substituting, in one or more of the multiple deposition cycles, at least a portion of the supply of the precursor substance with a dopant precursor, thereby doping the one or more atomic layers of the at least one first species.

The present disclosure will now be described in more detail with reference to exemplary embodiments thereof as shown in the accompanying drawings. While the present disclosure is described below with reference to exemplary embodiments, it should be understood that the present disclosure is not limited thereto. Those of ordinary skill in the art having access to the teachings herein will recognize additional implementations, modifications, and embodiments, as well as other fields of use, which are within the scope of the present disclosure as described herein, and with respect to which the present disclosure may be of significant utility.

### BRIEF DESCRIPTION OF THE DRAWINGS

In order to facilitate a fuller understanding of the present disclosure, reference is now made to the accompanying drawings, in which like elements are referenced with like numerals. These drawings should not be construed as limiting the present disclosure, but are intended to be exemplary only.

FIG. 1 shows a block diagram illustrating an exemplary atomic layer deposition cycle in accordance with an embodiment of the present disclosure.

FIG. 2 shows a block diagram illustrating an exemplary atomic layer deposition cycle in accordance with an embodiment of the present disclosure.

FIG. 3 shows a block diagram illustrating an exemplary system for atomic layer deposition in accordance with an embodiment of the present disclosure.

FIG. 4 shows a flow chart illustrating an exemplary method for atomic layer deposition in accordance with an embodiment of the present disclosure.

### DETAILED DESCRIPTION OF EXEMPLARY EMBODIMENTS

To solve the aforementioned problems associated with existing atomic layer deposition techniques, embodiments of the present disclosure introduce an ALD and in situ doping technique. Metastable atoms may be used to desorb excess atoms. The metastable atoms may be generated, for example, in a plasma chamber. For illustration purposes, the following description will focus on a method and apparatus for depositing doped or undoped silicon using helium metastable atoms. It should be appreciated that, with a same or similar technique, thin films of other species may also be grown using helium or other metastable atoms.

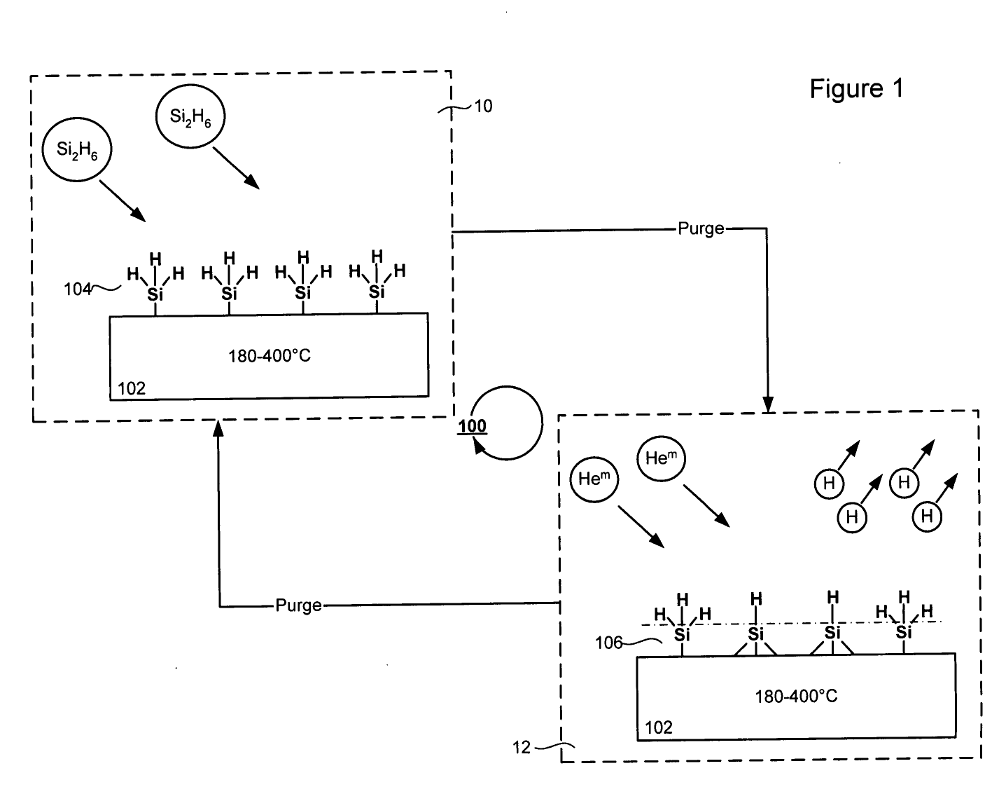

Referring to FIG. 1, there is shown a block diagram illustrating an exemplary atomic layer deposition cycle 100 in accordance with an embodiment of the present disclosure. The exemplary atomic layer deposition cycle 100 may comprise two phases, a saturation phase 10 and a desorption phase 12.

In the saturation phase 10, a substrate 102 may be exposed to a disilane (Si₂H₆) gas. For silicon film growth, the substrate surface may comprise, for example, silicon, silicon-on-insulator (SOI), and/or silicon dioxide. The disilane gas serves as a silicon precursor, and is supplied in a sufficiently high dose to saturate the substrate surface forming a disilane monolayer 104 thereon. Throughout this disclosure, however, use of the word “saturate” does not preclude the scenario where a substrate surface is only partially covered by a substance used to “saturate” such surface. The substrate 102 as well as the process environment may be kept at a carefully selected temperature to prevent the precursor gas from condensing or decomposing on the substrate surface. In this embodiment, the substrate 102 is heated to and maintained at a temperature between 180° C. and 400° C., although it is within the scope of the present disclosure to heat and maintain the substrate 102 within other temperature ranges.

In the desorption phase 12, the substrate 102 may be exposed to metastable atoms with sufficient energy to desorb the excess atoms from the precursor monolayer. According to this embodiment, helium metastable atoms may be used to desorb excess hydrogen atoms, either partially or completely, from the disilane monolayer 104 formed in the saturation phase 10. The helium metastable atoms may be created, for example, from a helium gas in an inductively coupled plasma. Each helium metastable atom may have an internal energy of approximately 20 eV, which can be used to break the bond between a silicon atom and a hydrogen atom. According to some embodiments, the metastable and other excited states of an inert gas (helium, argon, etc.) tend to emit photons that may also indirectly drive the desorption reactions at the substrate surface. After the excess hydrogen atoms have been removed, a silicon monolayer 106 may be formed on the substrate surface. According to some embodiments, not all of the excess hydrogen atoms may be removed. Therefore, at the end of the desorption phase 12, the surface of the silicon monolayer 106 may be a mixture of dangling bonds and hydrogen-terminated silicon atoms.

Between the saturation phase 10 and the desorption phase 12, the substrate surface may be purged with one or more inert gases (e.g., helium or argon) to remove the excess reaction gases as well as by-products (e.g., hydrogen). A complete cycle through the saturation phase 10 and the desorption phase 12, including the “purge” steps between the two phases, may be referred to as one “deposition cycle.” The deposition cycle 100 may be repeated to form a thin film of pure silicon (e.g., crystalline, polycrystalline, amorphous type, etc.), one monolayer (or fractional monolayer) at a time.

According to embodiments of the present disclosure, it may be advantageous to use metastable atoms rather than ions to desorb excess atoms from a substrate surface saturated with a precursor substance. Where the metastable atoms are generated in a plasma for desorption purposes, it may be desirable to prevent charged particles (e.g., electrons and ions) generated in the plasma from reaching the substrate surface, such that anisotropic film properties due to these charged particles may be reduced or minimized. A number of measures may be taken to prevent charged particles from affecting the ALD film formed on the substrate surface. For example, one or more devices (e.g., a baffle or screen) may be interposed between the plasma source and the substrate. These devices may further be biased filter out unwanted charged particles. Alternatively, an electromagnetic field may be set up to deflect charge particles. According to other embodiments, the orientation of the substrate surface may be adjusted to minimize the incident influx of charged particles. For example, the substrate platform may be inverted or otherwise turned away from the line of sight of the plasma source. Alternatively, the plasma source may be positioned at a distance from the substrate so as to cause a significant portion of the charged particles to fail to reach the substrate surface due to scattering or collisions.

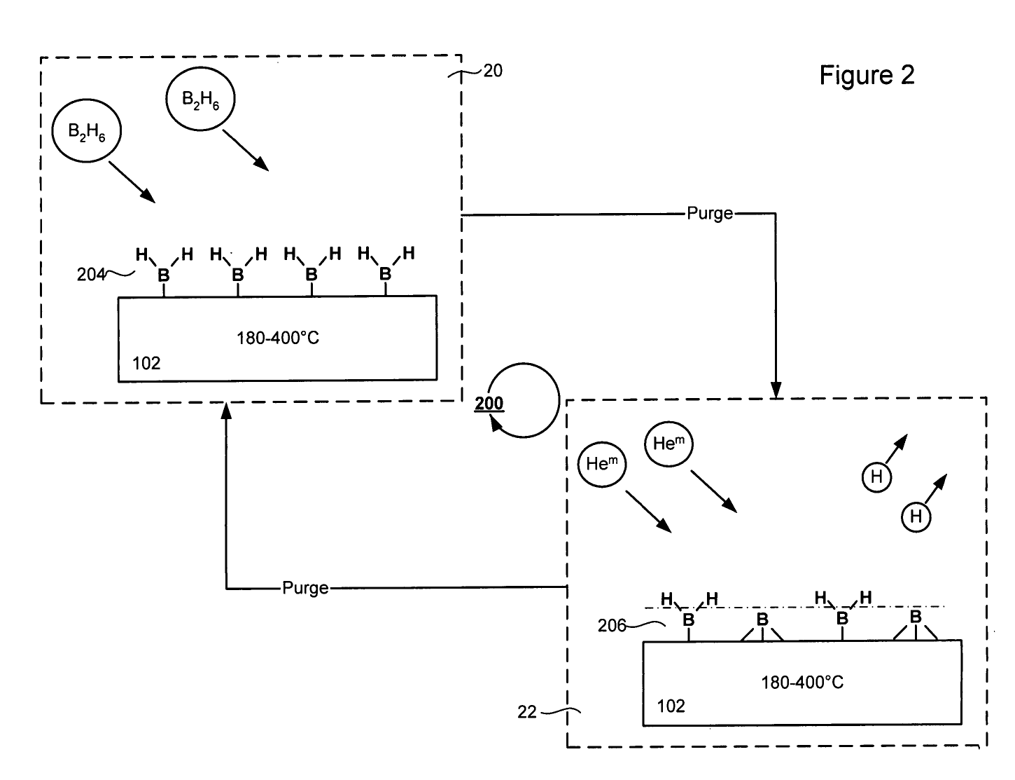

Referring to FIG. 2, there is shown a block diagram illustrating an exemplary atomic layer deposition cycle 200 in accordance with another embodiment of the present disclosure. According to this embodiment, the ALD process as illustrated in FIG. 1 above may be utilized not only to deposit a single-species thin film, but also to introduce impurities into the thin film or to form a multi-species and/or alternate-layered film, all in a well controlled manner. For example, apart from an undoped silicon film, a doped silicon film may also be grown based on a slightly modified ALD process. According to this modified ALD process, one or more deposition cycles 100 may be replaced with one or more deposition cycles 200.

In a saturation phase 20 of a deposition cycle 200, a dopant precursor gas may be provided in place of or concurrently with the silicon precursor gas. In the exemplary embodiment illustrated in FIG. 2, the dopant precursor is diborane (B₂H₆) which may adsorb (or “chemisorb”) to the surface of the substrate 102 to form a diborane monolayer 204. The underlying surface, in this case, may comprise a silicon monolayer deposited in a previous deposition cycle 100. The diborane monolayer 204 may partially or completely cover the underlying surface.

In a desorption phase 22 of a deposition cycle 200, the substrate 102 may be exposed to helium metastable atoms as described above. The helium metastable atoms may desorb excess hydrogen atoms from the diborane monolayer 204, leaving behind a partial or complete boron monolayer 206.

By controlling the number of deposition cycles 100 to be replaced with the deposition cycle 200, and by controlling the dose of diborane gas supplied in the saturation phase 20, a desired boron dopant density profile in the silicon film may be achieved. Since this in situ doping technique relies on conformal deposition of dopant atoms rather than ion implantation, it may achieve a uniform dopant distribution over the complex surface of a 3-D structure such as a FinFET. Further, there is no need for a post-deposition high-temperature diffusion process as required for ion implanted dopant atoms. Instead, no annealing or only a low-temperature annealing is needed, which results in reduced diffusion of the dopant species and therefore very abrupt (or “box-like”) dopant profiles. As such, embodiments of the present disclosure may be implemented at temperatures below 500° C., which is well within the semiconductor industry's “thermal budget.”

The atomic layer deposition in accordance with embodiments of the present disclosure may be a selective process depending on the substrate surface composition. For example, the process illustrated in FIG. 1 may deposit silicon monolayers on a silicon or SOI surface but not on a silicon dioxide (SiO₂) surface. Thus, silicon dioxide may be used as a masking layer to shield selected portions of the substrate surface.

It should be appreciated that, although only helium metastable atoms are used in the above examples, atoms of other species may also be chosen for the desorption process. Choice of these species may be based on the lifetime and energy of their metastable or excited states. Table 1 provides a list of candidate species whose metastable atoms may be used in the desorption phase of an ALD process.

TABLE 1

| Species | Lifetime (s) | Energy (eV) |
|---|---|---|
| He | 8000 | 19.8 |
| Ne | 24 | 17 |
| Ar | 40 | 12 |
| Kr | 30 | 10 |
| Xe | 43 | 8.4 |

It should also be appreciated that, apart from a diborane gas, other dopant precursors may also be used to introduce desired dopant atoms into ALD-formed thin films. Suitable dopant precursors for introducing dopant atoms such as boron (B), arsenic (As), phosphorus (P), indium (In), and antimony (Sb) may include but are not limited to the following classes of compounds: halides (e.g., BF₃), alkoxides (e.g., B(OCH₃)₃), alkyls (e.g., In(CH₃)₃), hydrides (e.g., AsH₃, PH₃), cyclopentadienyls, alkylimides, alkylamides (e.g., P[N(CH₃)₂] 3), and amidinates.

Further, the in situ doping technique, in which dopant-containing monolayers are deposited through an ALD-like process, is not limited to plasma-enhanced ALD processes. Nor does this in situ doping technique require the use of metastable atoms. For example, a thermal ALD process may also be adapted to form the dopant-containing monolayers. In fact, this in situ doping concept is applicable to any ALD process wherein one or more deposition cycles that deposit the monolayers of the thin film to be doped may be replaced with one or more deposition cycles that deposit the dopant-containing monolayers, or wherein the thin film to be doped may be deposited in substantially the same time as the dopant-containing monolayers.

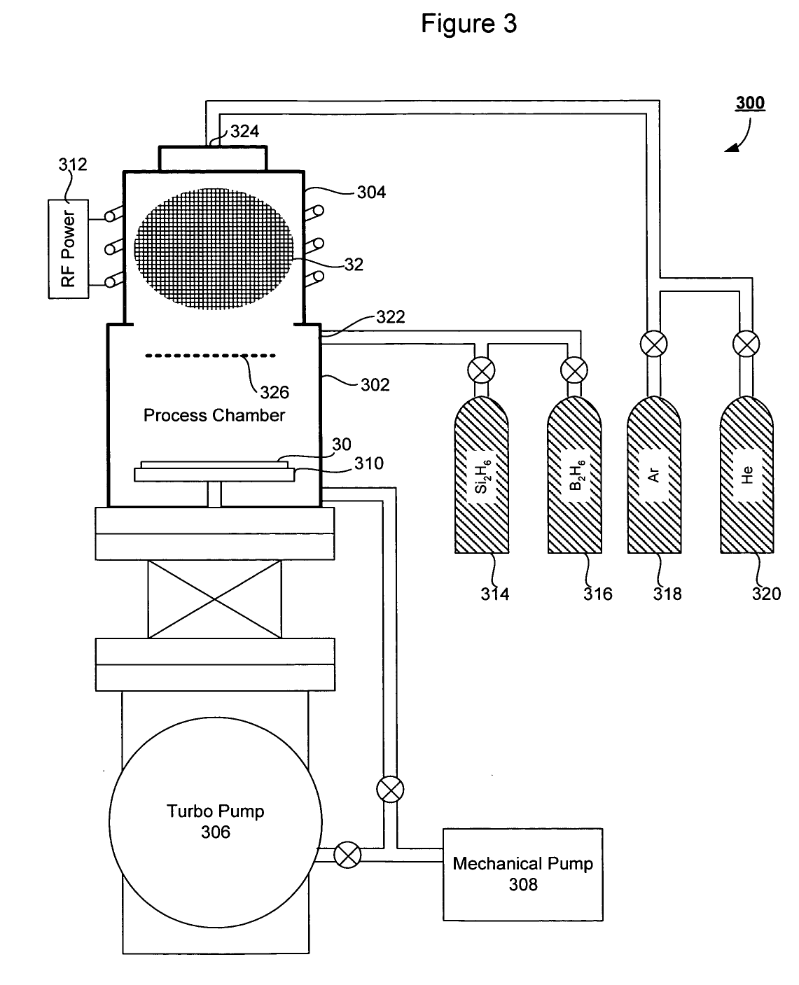

FIG. 3 shows a block diagram illustrating an exemplary system 300 for atomic layer deposition in accordance with an embodiment of the present disclosure.

The system 300 may comprise a process chamber 302, which is typically capable of a high vacuum base pressure (e.g., 10⁻⁷-10⁻⁶ torr) with, for example, a turbo pump 306, a mechanical pump 308, and other necessary vacuum sealing components. Inside the process chamber 302, there may be a substrate platform 310 that holds at least one substrate 30. The substrate platform 310 may be equipped with one or more temperature management devices to adjust and maintain the temperature of the substrate 30. Tilting or rotation of the substrate platform 30 may also be accommodated. The process chamber 302 may be further equipped with one or more film growth monitoring devices, such as a quartz crystal microbalance and/or a RHEED (reflection high energy electron diffraction) instrument.

The system 300 may also comprise a plasma chamber 304 which may be either coupled to or part of the process chamber 302. A radio frequency (RF) power supply 312 may be used to generate an inductively coupled plasma 32 inside the plasma chamber 304. For example, a helium gas supplied with a proper pressure may be excited by the RF power to generate a helium plasma which in turn generates helium metastable atoms.

The system 300 may further comprise a number of gas supplies, such as a disilane supply 314, a diborane supply 316, an argon supply 318, and a helium supply 320. Each gas supply may comprise a flow-control valve to set individual flow rates as desired. Alternately, the gas may be metered into the system by a series connection of, for example, a valve, a small chamber of fixed volume, and a second valve. The small chamber is first filled to the desired pressure by opening the first valve. After the first valve is closed, the fixed volume of gas is released into the chamber by opening the second valve. The disilane supply 314 and the diborane supply 316 may be coupled to the process chamber 302 through a first inlet 322, and may supply a sufficient amount of the respective silicon and boron precursor gases to saturate the substrate 30. The argon supply 318 and the helium supply 320 may be coupled to the plasma chamber 304 through a second inlet 324. The argon supply 318 may provide argon (or other inert gases) to purge the system 300. The helium supply 320 may supply a helium gas for plasma generation of helium metastable atoms. Optionally, there may be a screen or baffle device 326 between the plasma chamber 304 and the process chamber 302. The screen or baffle device 326, either biased or unbiased, may serve to prevent at least a portion of charged particles generated in the plasma chamber 304 from reaching the substrate 30.

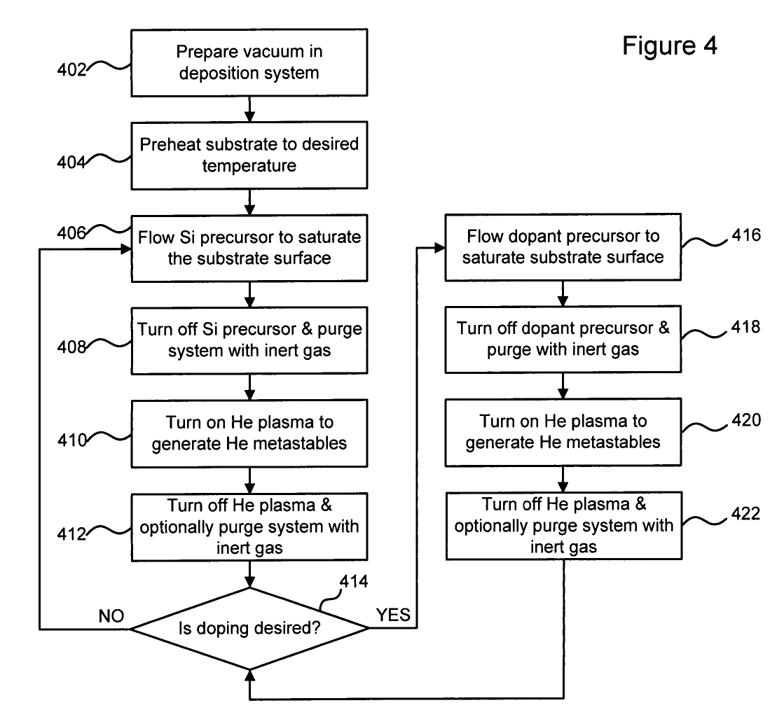

FIG. 4 shows a flow chart illustrating an exemplary method for atomic layer deposition in accordance with an embodiment of the present disclosure.

In step 402, a deposition system such as the one shown in FIG. 3 may be pumped down to a high-vacuum (HV) state. The vacuum condition may be achieved with any vacuum technology whether now known or later developed. The vacuum equipment may include, for example, one or more of a mechanical pump, a turbo pump, and a cryo pump. The vacuum level is preferably at least 10⁻⁷-10⁻⁶ torr, although it is within the scope of the present disclosure to maintain the vacuum level at other pressures. For example, if a higher film purity is desired, an even higher base vacuum may be needed. For a low-purity film, a lower vacuum may be acceptable.

In step 404, a substrate may be preheated to a desired temperature. The substrate temperature may be determined based on substrate type, ALD reaction species, desired growth rate, etc.

In step 406, a silicon precursor gas such as disilane (and its carrier gas, if any) may be flowed into a process chamber where the substrate sits. The silicon precursor gas may be supplied at a flow rate or pressure sufficient to saturate the substrate surface. The flow of disilane may last, for example, for a few seconds or up to a few tens of seconds. A monolayer of disilane may partially or completely cover the substrate surface.

In step 408, after surface saturation, the silicon precursor may be turned off and the deposition system may be purged with one or more inert gases to remove the excess silicon precursor.

In step 410, a helium plasma may be turned on. That is, a helium gas may be flowed from a plasma chamber to the process chamber. The helium plasma may be an inductively coupled plasma (ICP) or any of a number of other plasma types that provide enough excitation to the helium atoms to create helium metastable atoms. The substrate in the process chamber may be exposed to the helium metastable atoms so that they may react with the adsorbed silicon precursor thereon to desorb the non-silicon atoms. For example, for a disilane monolayer, the helium metastable atoms may help remove the excess hydrogen atoms to form a desired silicon monolayer. Exposure of the substrate surface to the metastable atoms may last, for example, for a few seconds or up to a few tens of seconds.

In step 412, the helium plasma may be turned off and the deposition system may be again purged with one or more inert gases.

In step 414, it may be determined whether any doping of the silicon film is desired. If doping is desired and it is an appropriate time to introduce dopants, the process may branch to step 416. Otherwise, the process may loop back to step 406 to start depositing a next monolayer of silicon and/or finish depositing a partial monolayer of silicon.

In step 416, a dopant precursor gas such as diborane (and its carrier gas, if any) may be flowed into the process chamber. The dopant precursor gas may be supplied at a flow rate or pressure sufficient to saturate the substrate surface. The flow of diborane may last, for example, for a few seconds or up to a few tens of seconds. A monolayer of diborane may partially or completely cover the substrate surface.

In step 418, after surface saturation, the dopant precursor may be turned off and the deposition system may be purged with one or more inert gases to remove the excess dopant precursor.

In step 420, the helium plasma may be turned on to generate helium metastable atoms. The substrate in the process chamber may again be exposed to the helium metastable atoms so that they may react with the adsorbed dopant precursor thereon to desorb the non-dopant atoms. For example, for a diborane monolayer, the helium metastable atoms may help remove the excess hydrogen atoms to form a desired partial or complete boron monolayer. Exposure of the substrate surface to the metastable atoms may last, for example, for a few seconds or up to a few tens of seconds.

In step 422, the helium plasma may be turned off and the deposition system may be again purged with one or more inert gases.

The above-described process steps of 406 through 412 and/or the process steps of 416 through 422 may be repeated until a desired silicon film with one or more monolayers with desired dopant profile has been obtained.

It should be understood that, although the above examples only describe the deposition and/or doping of a silicon film, embodiments of the present disclosure may be easily adapted to deposit or dope thin films of other materials or species. For example, ALD thin films containing the following species may also be deposited or doped: germanium (Ge), carbon (C), gallium (Ga), arsenic (As), indium (In), aluminum (Al), or phosphorus (P). The resulting thin film may contain a single species such as carbon or germanium, or a compound such as III-V compounds (e.g., GaAs, InAlP). For this purpose, a precursor substance containing the corresponding species may be utilized. Candidates for the precursor substance may include but are not limited to: hydrides (e.g. SiH₄, Si₂H₆, GeH₄) or halogenated hydrides (e.g. SiHCl₃), halogenated hydrocarbons (such as CHF₃), alkyls (e.g. trimethyl aluminum—Al(CH₃)₃, or dimethyl ethyl aluminum—CH₃CH₂—Al(CH₃)₂), or halides (such as CCl₄ or CCl₂F₂).

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. An apparatus for atomic layer deposition, the apparatus comprising:
a process chamber having a substrate platform to hold at least one substrate;
a supply of a precursor substance, wherein the precursor substance comprises atoms of at least one first species and atoms of at least one second species, and wherein the supply provides the precursor substance to saturate a surface of the at least one substrate; and
a plasma source of metastable atoms of at least one third species, wherein the metabstable atoms are capable of desorbing the atoms of the at least one second species from the saturated surface of the at least one substrate to form one or more atomic layers of the at least one first species.

2. The apparatus according to claim 1 further comprising one or more devices for preventing at least a portion of charged particles generated in the plasma source from reaching the substrate surface.

3. The apparatus according to claim 1, wherein the substrate platform is so oriented as to prevent at least a portion of charged particles generated in the plasma source from reaching the substrate surface.

4. The apparatus according to claim 1 further comprising a supply of a dopant precursor, wherein the supply of the dopant precursor is configured to substitute the supply of the precursor substance in one or more deposition cycles, thereby doping the one or more atomic layers of the at least one first species.

5. The apparatus according to claim 1 further comprising a supply of a dopant precursor, wherein, in one or more deposition cycles, the supply of the dopant precursor is configured to supply the dopant precursor at substantially the same time when the supply of the precursor substance supplies the precursor substance, thereby doping the one or more atomic layers of the at least one first species.

6. The apparatus according to claim 1, wherein the plasma source of metastable atoms further comprises a plasma chamber coupled to the process chamber, the plasma chamber being adapted to generate the metastable atoms of the at least one third species.

7. The apparatus according to claim 6, wherein the plasma chamber generates the metastable atoms of the at least one third species from an inductively coupled plasma.

8. The apparatus according to claim 1, wherein the precursor substance comprises one or more species selected from a group consisting of:
silicon;
carbon;
germanium;
gallium;
arsenic;
indium;
aluminum; and
phosphorus.

9. The apparatus according to claim 1, wherein the substrate surface comprises one or more materials selected from a group consisting of:
silicon;
silicon-on-insulator (SOI);
silicon dioxide;
diamond;
silicon germanium;
silicon carbide;
a III-V compound;
a flat panel material;
a polymer; and
a flexible substrate material.

10. The apparatus according to claim 1, wherein the at least one third species comprises one or more species selected from a group consisting of:
helium (He);
neon (Ne);
argon (Ar);
krypton (Kr);
radon (Rn); and
xenon (Xe).

11. The apparatus according to claim 1, wherein the at least one substrate is kept at a temperature below 500° C.

12. A method for atomic layer deposition, the method comprising the steps of:
saturating a substrate surface with a precursor substance having atoms of at least one first species and atoms of at least one second species, thereby forming a monolayer of the precursor substance on the substrate surface; and
exposing the substrate surface to plasma-generated metastable atoms of a third species, wherein the metastable atoms desorb the atoms of the at least one second species from the substrate surface to form an atomic layer of the at least one first species.

13. An atomic layer deposition method comprising multiple deposition cycles to form a plurality of atomic layers of the first species, wherein each deposition cycle repeats the steps as recited in claim 12 to form one atomic layer of the first species.

14. The method according to claim 13, further comprising:
supplying the substrate surface with a dopant precursor, concurrently with a supply of the precursor substance, in one or more of the multiple deposition cycles to dope the plurality of atomic layers of the at least one first species.

15. The method according to claim 13, further comprising:
substituting the precursor substance with a dopant precursor in one or more of the multiple deposition cycles to dope the plurality of atomic layers of the at least one first species.

16. The method according to claim 13, further comprising:
preventing at least a portion of charged particles generated in a plasma source of the metastable atoms from reaching the substrate surface.

17. The method according to claim 13, further comprising:
annealing the substrate surface at a temperature below 500° C.

18. The method according to claim 13, wherein:
the precursor substance comprises disilane (Si₂H₆);
the at least one first species comprises silicon;
the at least one second species comprises hydrogen; and
the third species comprises helium.

19. The method according to claim 18, further comprising:
masking one or more selected portions of the substrate surface with silicon dioxide (SiO₂).

20. The method according to claim 13, wherein the precursor substance comprises one or more species selected from a group consisting of:
silicon;
carbon;
germanium;
gallium;
arsenic;
indium;
aluminum; and
phosphorus.

21. The method according to claim 13, wherein the substrate surface comprises one or more materials selected from a group consisting of:
silicon;
silicon-on-insulator (SOI);
silicon dioxide;
diamond;
silicon germanium;
silicon carbide;
a III-V compound;
a flat panel material;
a polymer; and
a flexible substrate material.

22. The method according to claim 13, wherein the at least one third species comprises one or more species selected from a group consisting of:
helium (He);
neon (Ne);
argon (Ar);
krypton (Kr);
radon (Rn); and
xenon (Xe).

23. An apparatus for atomic layer deposition, the apparatus comprising:
a process chamber having a substrate platform to hold at least one substrate;
a supply of disilane (Si₂H₆), wherein the supply is adapted to supply a sufficient amount of disilane to saturate a surface of the at least one substrate;
a supply of helium; and
a plasma chamber coupled to the process chamber, the plasma chamber being adapted to generate helium metastable atoms from helium supplied by the supply of helium;
wherein the metabstable atoms are capable of desorbing hydrogen atoms from the saturated surface of the at least one substrate, thereby forming one or more atomic layers of silicon.

24. The apparatus according to claim 23, further comprising a supply of diborane (B₂H₆), wherein the supply of diborane is configured to substitute at least a portion of the supply of disilane in one or more deposition cycles, thereby introducing boron atoms to the one or more atomic layers of silicon.

25. A method of conformal doping comprising:
forming a thin film on a substrate surface in one or more deposition cycles, wherein, in each of the one or more deposition cycles, a precursor substance having atoms of at least one first species and atoms of at least one second species is supplied to saturate the substrate surface, and then the atoms of the at least one second species are desorbed from the saturated substrate surface to form one or more atomic layers of the at least one first species; and
substituting, in one or more of the multiple deposition cycles, at least a portion of the supply of the precursor substance with a dopant precursor, thereby doping the one or more atomic layers of the at least one first species.

26. The method according to claim 25, wherein the atoms of the at least one second species are desorbed with metastable atoms of at least one third species.

27. The method according to claim 25, wherein the metastable atoms of the at least one third species are generated with a plasma.

28. The method according to claim 27, wherein at least a portion of charged particles are prevented from reaching the substrate surface.

29. The method according to claim 27, wherein the at least one third species comprises one or more species selected from a group consisting of:
helium (He);
neon (Ne);
argon (Ar);
krypton (Kr);
radon (Rn); and
xenon (Xe).

30. The method according to claim 25, wherein the precursor substance comprises one or more species selected from a group consisting of:
silicon;
carbon;
germanium;
gallium;
arsenic;
indium;
aluminum; and
phosphorus.

31. The method according to claim 25, wherein the substrate surface comprises one or more materials selected from a group consisting of:
silicon;
silicon-on-insulator (SOI);
silicon dioxide;
diamond;
silicon germanium;
silicon carbide;
a III-V compound;
a flat panel material;
a polymer; and
a flexible substrate material.

32. The method according to claim 25, wherein the substrate surface is kept at a temperature below 500° C.

33. The method according to claim 25, wherein the substrate surface is not subject to a further thermal process that re-distributes atoms of the dopant precursor.

34. The method according to claim 25, wherein the substrate surface has a three-dimensional topology and the thin film is conformally formed and conformally doped thereon.

35. The method according to claim 34, wherein the thin film is part of a FinFET structure.
